(19) United States
(12) Patent Application Publication
(10) Pub. No.: US 2003/0169107 A1
(43) Pub. Date: Sep. 11, 2003

(54) Method and system for proportional plus integral loop compensation using a hybrid of switched capacitor and linear amplifiers

(76) Inventor: Robert LeChevalier, Golden, CO (US)

Correspondence Address: KNOBBE MARTENS OLSON & BEAR LLP, 2040 MAIN STREET, FOURTEENTH FLOOR, IRVINE, CA, 92614, US

(21) Appl. No.: 10/274,429

(22) Filed: Oct. 17, 2002

Related U.S. Application Data
(60) Provisional application No. 60/342,637, filed on Oct. 19, 2001.
(60) Provisional application No. 60/343,856, filed on Oct. 19, 2001.
(60) Provisional application No. 60/343,638, filed on Oct. 19, 2001.
(60) Provisional application No. 60/342,582, filed on Oct. 19, 2001.
(60) Provisional application No. 60/346,102, filed on Oct. 19, 2001.
(60) Provisional application No. 60/353,753, filed on Oct. 19, 2001.
(60) Provisional application No. 60/342,793, filed on Oct. 19, 2001.
(60) Provisional application No. 60/342,791, filed on Oct. 19, 2001.
(60) Provisional application No. 60/343,370, filed on Oct. 19, 2001.
(60) Provisional application No. 60/342,783, filed on Oct. 19, 2001.
(60) Provisional application No. 60/342,794, filed on Oct. 19, 2001.

(51) Int. Cl. H03F 3/68

(52) U.S. Cl. 330/124 R

(57) ABSTRACT

A proportional plus integral compensation network employs a combination of linear components and switched capacitor components so as to reduce the physical size of the components required to implement the network. The compensation network comprises a linear, proportional amplifier, an integrator, in parallel with the amplifier, having a switched capacitor as a resistive element, and a summing element to combine the output signals of the amplifier and the integrator to provide a stable, amplified feedback signal.

### RELATED APPLICATIONS

This application claims priority to, and hereby incorporates by reference, the following patent applications:

U.S. Provisional Patent Application No. 60/342,637, filed on Oct. 19, 2001, entitled PROPORTIONAL PLUS INTEGRAL LOOP COMPENSATION USING A HYBRID OF SWITCHED CAPACITOR AND LINEAR AMPLIFIERS (Attorney Docket No. CLMCR.009PR);

U.S. Provisional Patent Application No. 60/343,856, filed on Oct. 19, 2001, entitled CHARGE PUMP ACTIVE GATE DRIVE (Attorney Docket No. CLMCR.010PR);

U.S. Provisional Patent Application No. 60/343,638, filed on Oct. 19, 2001, entitled CLAMPING METHOD AND APPARATUS FOR SECURING A MINIMUM REFERENCE VOLTAGE IN A VIDEO DISPLAY BOOST REGULATOR (Attorney Docket No. CLMCR.011PR);

U.S. Provisional Patent Application No. 60/342,582, filed on Oct. 19, 2001, entitled PRECHARGE VOLTAGE ADJUSTING METHOD AND APPARATUS (Attorney Docket No. CLMCR.013PR);

U.S. Provisional Patent Application No. 60/346,102, filed on Oct. 19, 2001, entitled EXPOSURE TIMING COMPENSATION FOR ROW RESISTANCE (Attorney Docket No. CLMCR.014PR);

U.S. Provisional Patent Application No. 60/353, 753, filed on Oct. 19, 2001 entitled METHOD AND SYSTEM FOR PRECHARGING OLED/PLED DISPLAYS WITH A PRECHARGE SWITCH LATENCY (Attorney Docket No. CLMCR.015PR);

U.S. Provisional Patent Application No. 60/342,793, filed on Oct. 19, 2001, entitled ADAPTIVE CONTROL BOOST CURRENT METHOD AND APPARATUS, filed on Oct. 19, 2001 (Attorney Docket No. CLMCR.017PR);

U.S. Provisional Patent Application No. 60/342,791, filed on Oct. 19, 2001, entitled PREDICTIVE CONTROL BOOST CURRENT METHOD AND APPARATUS (Attorney Docket No. CLMCR.018PR);

U.S. Provisional Patent Application No. 60/343,370, filed on Oct. 19, 2001, entitled RAMP CONTROL BOOST CURRENT METHOD AND APPARATUS (Attorney Docket No. CLMCR.019PR);

U.S. Provisional Patent Application No. 60/342,783, filed on Oct. 19, 2001, entitled ADJUSTING PRECHARGE FOR CONSISTENT EXPOSURE VOLTAGE (Attorney Docket No. CLMCR.020PR); and

U.S. Provisional Patent Application No. 60/342,794, filed on Oct. 19, 2001, entitled PRECHARGE VOLTAGE CONTROL VIA EXPOSURE VOLTAGE RAMP (Attorney Docket No. CLMCR.021PR);

This application is related to, and hereby incorporates by reference, the following patent applications:

U.S. Provisional Application No. 60/290,100, filed May 9, 2001, entitled “METHOD AND SYSTEM FOR CURRENT BALANCING IN VISUAL DISPLAY DEVICES”, (Attorney Docket No. CLMCR.004PR);

U.S. patent application entitled “CURRENT BALANCING CIRCUIT”, filed May 7, 2002 (Attorney Docket No. CLMCR.004A);

U.S. patent application entitled “CURRENT BALANCING CIRCUIT”, filed May 7, 2002 (Attorney Docket No. CLMCR.004A1);

U.S. patent application Ser. No. 09/904,960, filed Jul. 13, 2001, entitled “BRIGHTNESS CONTROL OF DISPLAYS USING EXPONENTIAL CURRENT SOURCE” (Attorney Docket No. CLMCR.005A);

U.S. patent application Ser. No. 10/141659, filed on May 7, 2002, entitled “MATCHING SCHEME FOR CURRENT CONTROL IN SEPARATE I.C.S.” (Attorney Docket No. CLMCR.006A);

U.S. patent application Ser. No. 10/141326, filed May 7, 2002, entitled “MATCHING SCHEME FOR CURRENT CONTROL IN SEPARATE I.C.S.” (Attorney Docket No. CLMCR.006A1);

U.S. patent application Ser. No. 09/852,060, filed May 9, 2001, entitled “MATRIX ELEMENT VOLTAGE SENSING FOR PRECHARGE” (Attorney Docket No. CLMCR.008A);

U.S. patent application entitled “METHOD AND SYSTEM FOR CHARGE PUMP ACTIVE GATE DRIVE”, filed on even date herewith (Attorney Docket No. CLMCR.010A);

U.S. patent application entitled “METHOD AND CLAMPING APPARATUS FOR SECURING A MINIMUM REFERENCE VOLTAGE IN A VIDEO DISPLAY BOOST REGULATOR”, filed on even date herewith (Attorney Docket No. CLMCR.011A);

U.S. patent application Ser. No. 10/141,648, filed May 7, 2002, entitled “APPARATUS FOR PERIODIC ELEMENT VOLTAGE SENSING TO CONTROL PRECHARGE” (Attorney Docket No. CLMCR.012A);

U.S. patent application Ser. No. 10/141,318, filed May 7, 2002, entitled “METHOD FOR PERIODIC ELEMENT VOLTAGE SENSING TO CONTROL PRECHARGE,” (Attorney Docket No. CLMCR.012A1);

U.S. patent application entitled “MATRIX ELEMENT PRECHARGE VOLTAGE ADJUSTING APPARATUS AND METHOD”, filed on even date herewith (Attorney Docket No. CLMCR.013A);

U.S. patent application entitled “SYSTEM AND METHOD FOR EXPOSURE TIMING COMPENSATION FOR ROW RESISTANCE”, filed on even date herewith (Attorney Docket No. CLMCR.014A)

U.S. patent application entitled “METHOD AND SYSTEM FOR PRECHARGING OLED/PLED DISPLAYS WITH A PRECHARGE LATENCY”, filed on even date herewith (Attorney Docket No. CLMCR.015A);

U.S. Provisional Application 60/348,168 filed Oct. 19, 2001, entitled “PULSE AMPLITUDE MODULATION SCHEME FOR OLED DISPLAY DRIVER”, filed on even date herewith (Attorney Docket No. CLMCR.016PR);

U.S. patent application Ser. No. 10/029563, filed Dec. 20, 2001, entitled “METHOD OF PROVIDING PULSE AMPLITUDE MODULATION FOR OLED DISPLAY DRIVERS” (Attorney Docket No. CLMCR.016A);

U.S. patent application Ser. No. 10/029605, filed Dec. 20, 2001, entitled “SYSTEM FOR PROVIDING PULSE AMPLITUDE MODULATION FOR OLED DISPLAY DRIVERS” (Attorney Docket No. CLMCR.016A1);

U.S. patent application entitled “ADAPTIVE CONTROL BOOST CURRENT METHOD AND APPARATUS”, filed on even date herewith (Attorney Docket No. CLMCR.017A);

U.S. patent application entitled “PREDICTIVE CONTROL BOOST CURRENT METHOD AND APPARATUS”, filed on even date herewith (Attorney Docket No. CLMCR.018A);

U.S. patent application entitled “RAMP CONTROL BOOST CURRENT METHOD”, filed on even date herewith (Attorney Docket No. CLMCR.019A);

U.S. patent application entitled “METHOD AND SYSTEM FOR ADJUSTING PRECHARGE FOR CONSISTENT EXPOSURE VOLTAGE”, filed on even date herewith (Attorney Docket No. CLMCR.020A);

U.S. patent application entitled “METHOD AND SYSTEM FOR RAMP CONTROL OF PRECHARGE VOLTAGE”, filed on even date herewith (Attorney Docket No. CLMCR.021A).

### BACKGROUND OF THE INVENTION

1. Field of the Invention

The present invention relates to power conversion circuits, and more particularly to compensation in power conversion circuits.

2. Description of the Related Art

Information display screens typically use rows of light emitting devices to display a desired image or compilation of data. The light emitting devices require generally large current sources in the case all the devices must “light up” at the same time. For portable or handheld devices the amount of current or power available is limited by the size of the current or power generator and therefore small power supplies are typically used in combination with power conversion circuits, or boost regulators in the display device. For stability and reliability in operation these boost regulators generally require some kind of compensation feedback loop for control in the circuit.

Feedback loops often implement “proportional plus integral compensation,” which comprises summing the output signals of a proportional amplifier and an integrator, so as to simultaneously obtain a fast, stable dynamic response with low control error. The circuit diagram of FIG. 1 illustrates an implementation of the prior art compensation. In the event the compensation network uses analog circuitry, the loop can either be implemented as all-linear (continuous time) circuits or all discrete-time switched capacitor circuits. The limitations of all-linear circuits, as shown in FIG. 1, include the typical requirement of a very high valued capacitor 110 in the integrator portion 112 of the compensation loop along with a high valued resistor 114 in order to obtain the desired compensation in a feedback loop. In this case a value of 400 pF is used for the capacitor 110 and a 1MΩ resistor 114 is used. The use of a high valued capacitor 110 is impractical for incorporation on-chip in a fully integrated implementation because of the space requirement for such a capacitor, and such capacitors tend to also be very costly. The limitations of an all-switched capacitor implementation include the often inability of the loop dynamics to tolerate the extra delay of a clock period in the proportional path of the loop introduced by a switched capacitor implementation, which leads to instability of the compensation network under certain loading conditions.

Continuous time and discrete time components are traditionally not intermingled in design in proportional plus integral compensation, and the theories behind the two approaches are typically not combined in presentation. Discrete time control loops are common in the art. However, such control loops are typically implemented using microprocessors. The use of microprocessors doesn't easily provide for the addition of a continuous time proportional path in a compensation network.

The inability to incorporate the large capacitors of an all linear implementation of a proportional plus integral compensation network on chip, and the instability of an all switched capacitor implementation create a problem for circuits demanding the use of proportional plus integral control in a chip embodiment.

Accordingly, an effective proportional plus integral compensation loop employing the use of both small components for on-chip use and a combination of components that provide stability in the feedback network is needed in the art.

### SUMMARY OF THE INVENTION

A compensation network circuit comprises a linear amplifier, an integrator in parallel with the linear amplifier which includes a switched capacitor providing an effective resistance, and a summing element connected to an output of the linear amplifier and an output of the integrator so as to provide a stable, amplified feedback signal. The linear amplifier may comprise a first resistor having an output and receiving an input signal from a voltage source, an operational amplifier having an inverting input connected to the output of the first resistor, a second resistor connected in the feedback path of the operational amplifier, and a reference voltage input connected to a non-inverting input of the operational amplifier.

The switched capacitor of the compensation network circuit may comprise a first switch receiving a first clock input, a first capacitor having an input connected to an output of the first switch and an output connected to ground, and a second switch having a second clock input and an input connected to the first capacitor. The first switch and the second switch can be switching MOSFET's. The integrator may further comprise an operational amplifier having an inverting input connected to an output of the second switch, and a non-inverting input connected to the reference voltage and an output from the operational amplifier.

The summing element of the compensation network circuit can be a passive resistor summing network or an active amplifier. The compensation network circuit may be implemented in a power conversion circuit and/or a portable display device.

A proportional plus integral compensation network comprises an input voltage, a proportional amplifier, an integrator, and a summing element. The proportional amplifier comprises a first impedance element receiving the input voltage, and an output connected to an inverting input of a first operational amplifier, a reference voltage connected to a non-inverting input of the operational amplifier, and a second impedance element connected in the feedback path of the operational amplifier and an output from the first operational amplifier.

The integrator comprises a first switch receiving the input voltage and a first clock signal, a first capacitor receiving an output of said first switch, and an output connected to ground, a second switch connected to the first capacitor, receiving a second clock signal, and a second operational amplifier having an inverting input from an output of the second switch, a non-inverting input receiving the reference voltage, a second capacitor in a feedback path of the second operational amplifier, and an output from the second operational amplifier. The first switch and the second switch may be switching MOSFET's.

The summing element may comprise a first resistive element receiving an input from the output of the first operational amplifier and an output, and a second resistive element receiving an input from the output of the second operational amplifier and having an output connected to the output of the first resistive element of the summing network so as to provide a stable, amplified feedback signal.

A power conversion circuit comprises a voltage input, a clock input, a flip flop receiving said voltage input and having a reset input, an output, and an inverted output. The power conversion circuit further comprises a boost circuit connected to an output of the switch, a linear amplifier receiving a voltage output from the boost circuit, and an integrator in parallel with the linear amplifier, receiving the voltage output and having a switched capacitor which provides an effective resistance. The power conversion circuit also comprises a summing element connected to an output of the linear amplifier and an output of the integrator so as to provide a stable, amplified feedback signal, a switch control circuit receiving the stable, amplified feedback signal from the summing network and having an output connected to the reset input of the flip flop.

A method of loop compensation comprises proportionally amplifying an input with a linear amplifier, integrating the input using at least one switched capacitor, and summing the amplified input and the integrated input so as to produce a stable, amplified feedback signal. The act of summing may performed by a passive resistor summing network or an active amplifier. The method may further comprise controlling a power converter circuit using the method of loop compensation. The method may be performed in a portable display device.

A compensation network circuit comprises a signal input, a first signal path having linear components and receiving said signal input, a second signal path having at least one switched capacitor and receiving the signal input, and a summing network receiving a signal from an output of the first path and an output of the second path so as to provide a stable, amplified output signal.

The first signal path of the compensation network circuit may comprise a first resistor receiving the signal input, an operational amplifier having an input connected to an output of the first resistor and an input receiving a reference voltage, a second resistor in a feedback path of the operational amplifier, and an output connected to an output of the operational amplifier.

The switched capacitor of the compensation network circuit may comprise a first switch receiving a first clock input, a first capacitor having an input connected to an output of the first switch and an output connected to ground, and a second switch having a second clock input and an input connected to the first capacitor. The first switch and the second switch can be switching MOSFET's. The second signal path may comprise an integrator.

A method of loop compensation comprises means for proportionally amplifying a signal input with a linear amplifier, means for integrating the signal input using at least one switched capacitor, and means for summing the amplified signal and the integrated signal so as to provide a stable, amplified signal. The switched capacitor may comprise a first switch receiving a first clock input, a first capacitor having an input connected to an output of the first switch and an output connected to ground, and a second switch having a second clock input and an input connected to the first capacitor.

In the method of loop compensation, the first switch and the second switch can be switching MOSFET's. The act of summing can be performed by a passive resistor summing network. The method may further comprise controlling a power converter circuit using the method of loop compensation. The method can be performed in a portable display device.

A compensation circuit comprises a signal input, a first signal path, receiving the signal input and having an output, a second signal path, receiving the signal input and having an output. The second signal path comprises an integrator, having an input and an output, wherein the integrator includes a switched capacitor which provides an effective resistance, a transconductance amplifier, having an input coupled to the output of the integrator, and an output. The compensation circuit further comprises a linear amplifier having an input coupled to the output of the first signal path and the output of the second signal path, and an output so as to provide a stable, amplified feedback signal.

The first signal path can have an input from a voltage source and comprise a resistor having an output. The linear amplifier can further comprise an operational amplifier having an inverting input connected to the first signal path and the output of the transconductance amplifier, and a resistor connected in the feedback path of the operational amplifier.

In the compensation circuit, the switched capacitor can comprise a first switch receiving a first clock input and having an output, a first capacitor having an input connected to the output of the first switch and an output connected to ground, and a second switch having a second clock input and an input connected to the first capacitor.

In the compensation circuit, the integrator can further comprise an operational amplifier having an inverting input connected to the output of the second switch, a non-inverting input connected to the reference voltage.

Another aspect of the invention concerns a method of loop compensation. The method comprises proportionally amplifying an input with a linear amplifier, integrating the input using at least one switched capacitor, and summing the amplified input and the integrated input to produce a stable, amplified feedback signal.

### BRIEF DESCRIPTION OF THE DRAWINGS

FIG. 1 is a circuit diagram of an all linear component proportional plus integral feedback loop.

FIG. 2 is a block diagram of a regulator circuit.

FIG. 3 is a block diagram providing additional detail to the block diagram of FIG. 2.

FIG. 4 is a graph of the output voltages of the proportional amplifier, the integrator, and the summing element of the circuit of FIG. 3.

FIG. 5 is a timing diagram illustrating the operation of the circuit of FIG. 3.

FIG. 6 is a circuit diagram of one embodiment of the proportional plus integral compensation network of the invention.

FIG. 7 is a circuit diagram of one embodiment of the proportional plus integral compensation network of the invention.

FIG. 8 is a timing diagram of the non-overlapping logic circuit used for the input to the switching MOSFET's of the switching capacitors of FIG. 6.

### DETAILED DESCRIPTION OF THE INVENTION

The invention is shown in an exemplary functional environment of a regulator circuit for use in a video display screen. Particular components are described in more detail than others, and more general functional components are described in less detail where a person having skill in the art would understand their function and implementation requirements.

The invention is directed to a proportional plus integral compensation network which is implemented with a combination of discrete time and continuous time components. In one embodiment of the invention a linear amplifier is used in combination with an integrator employing switched capacitors. This combination of components allows for incorporation of the compensation network on-chip due to the reduced size of the components as a result of the design.

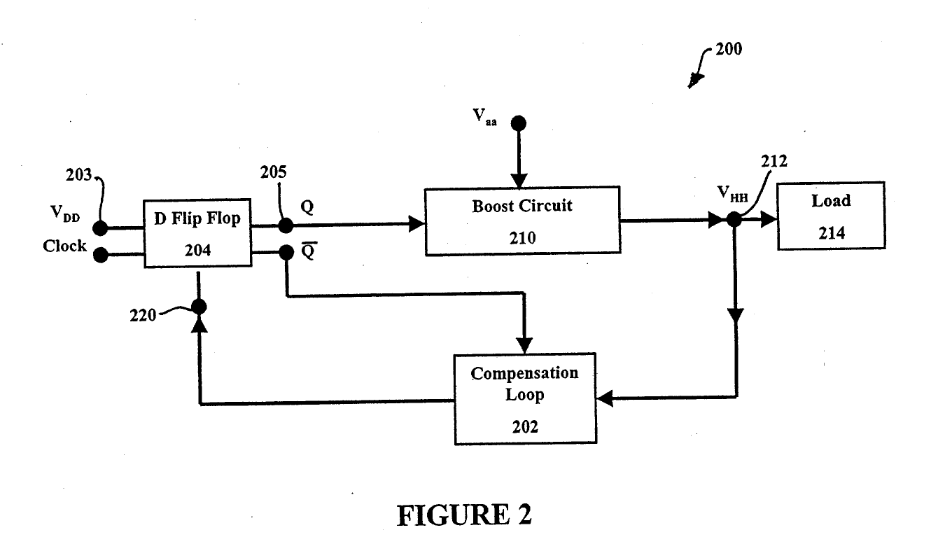

The compensation network is implemented in a regulator circuit which boosts an input voltage from about 2 Volts to 20 Volts for use in a portable video display screen. A block diagram of a regulator circuit 200 is shown in FIG. 2 having a compensation loop 202. The regulator circuit comprises a voltage input 203 and a clock cycle input to a D-type flip flop 204 having an output Q 205 which is connected to a boost circuit 210. The boost circuit 210 has a voltage output V_{HH} 212 connected in series to a load 214. The voltage output 212 is also fed to the input of the compensation loop 202. The output of the compensation loop 202 is connected to a reset input 220 of the flip flop 204.

The reset input 220, in this embodiment of the invention, utilizes an inverted reset operation, that is the reset value is nominally high, and when the reset input is low, the output Q 205 of the flip flop 204 is reset. It will be appreciated, however, that a non-inverted reset operation can be used and implemented in the regulator circuit 200.

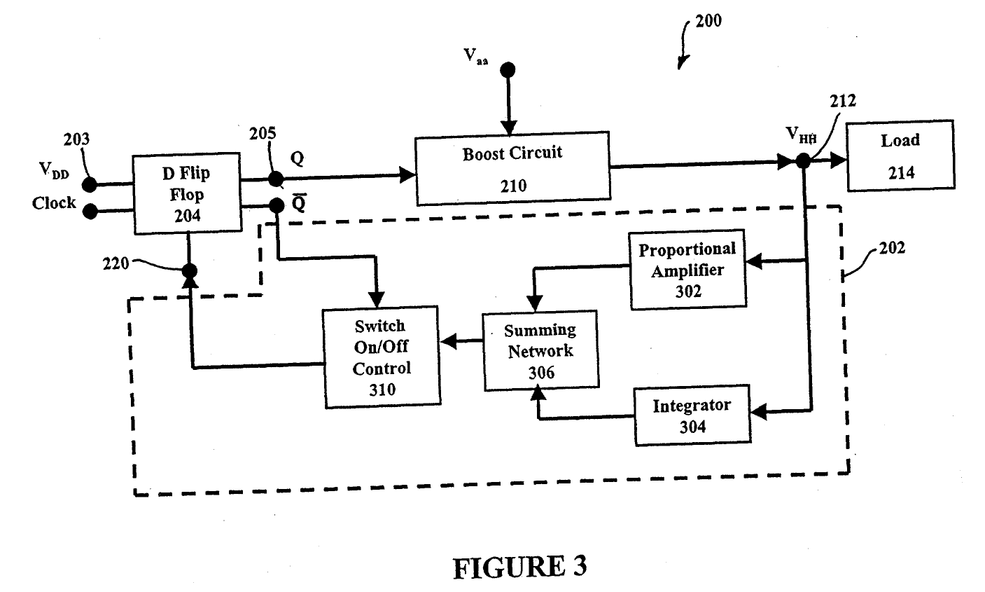

FIG. 3 is a block diagram providing additional detail to the block diagram of FIG. 2. The compensation loop 202 is shown comprising a proportional amplifier 302 in parallel with an integrator 304, whose outputs are summed at a summing element 306. The output of the summing element 306 is connected to a switch on/off control block 310 along with the output of the flip flop 204. The output of the switch on/off control block 310 is connected to the reset input 220 of the flip flop 204.

The switch on/off time control 310 is implemented in this design to provide switch timing to the boost circuit 210 according to the operation of the proportional plus integral compensation network. An additional function of the switch on/off control 310 is to limit the maximum on-time of the flip flop 204 such that the flip flop 204 can be turned off during the initial startup of the regulator circuit 200.

The operation of the compensation loop 202 will now be discussed with regard to FIG. 3. The proportional amplifier 302 is used to apply gain to the measured output voltage 212 before it is applied to the switch off control 308. The gain is used to improve the phase margin of the compensation loop 202. If the gain is too small the output voltage 212 won't regulate at the desired level and will be highly load dependent. The amount of gain required, however, typically makes the loop unstable. Therefore, the gain from the proportional amplifier 302 may be limited in order to provide stable operation of the loop 202.

To recover the gain of the proportional amplifier 302 of the compensation loop 202 the integrator 304 can be employed in parallel with the proportional amplifier 302. By including the integrator 304 the control error caused by the low loop gain of the proportional amplifier 302 is corrected and reduced to an acceptably low value. The outputs of the proportional amplifier 302 and the integrator 304 are then summed by the summing element 306 to provide both an amplified and stable feedback signal from the voltage output 212 of the circuit.

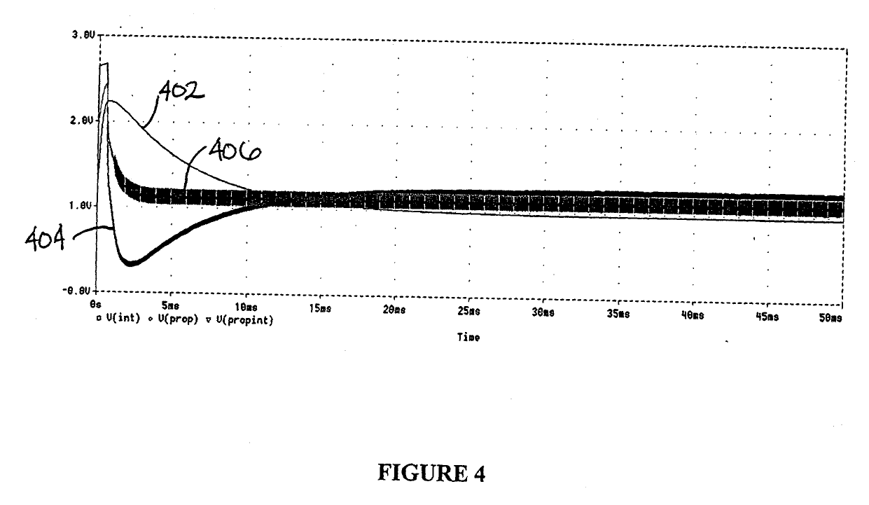

FIG. 4 is a graphical representation of the output voltages of the proportional amplifier 302, the integrator 304, and the output of the summing element 306 of the circuit of FIG. 3. As can be seen in FIG. 4, the output 402 of the integrator 304 compensates for the inaccuracy of the output 404 of the proportional amplifier 302, while together the proportional plus integral summed output 406 provides stable, accurate loop feedback control.

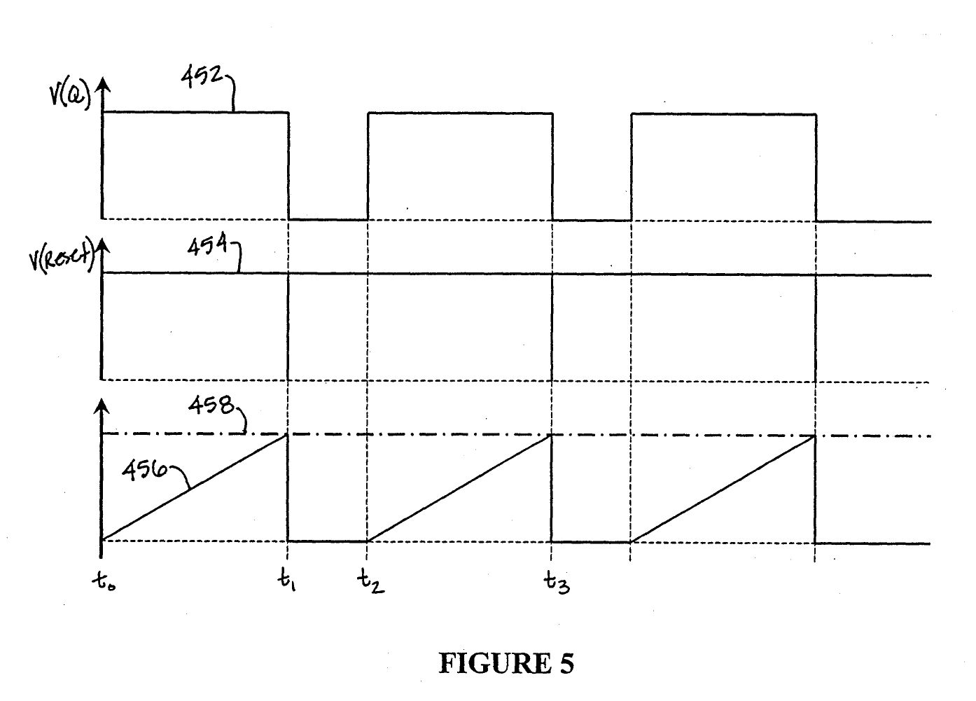

In one embodiment, the switch on/off control 310 can be implemented with a comparator having an input from the summing element 306 and an input from a pulse width modulated (PWM) ramp signal source. The ramp source PWM operation can be controlled by the inverted output of the flip flop 204. The output of the summing element 306 is compared to the ramp signal source by the comparator. When the output of the ramp signal reaches the level of the output of the summing element 306, a HIGH voltage signal is sent from the output of the switch on/off control 310 to the reset input 220 of the flip flop 204 to reset the output 205 of the flip flop 204. This switching operation is further described with respect to FIG. 5.

By resetting the flip flop 204 through the switch on/off control 310, the amount of time a switch (not shown) in the boost circuit 210 allows current to flow to an inductor (not shown) in the boost circuit 210 can be controlled such that the voltage level of the voltage output 212 is regulated at the correct level.

A timing diagram is shown in FIG. 5 illustrating the operation of the regulator circuit 200 with the exemplary implementation of the switch on/off control 310 previously discussed. A trace 452 illustrates the voltage output 205 of the flip flop 204, a trace 454 illustrates the voltage at the reset input 220 of the flip flop 204, a trace 456 illustrates the voltage output of a PWM ramp signal source, and a trace 458 illustrates the voltage output of the summing element 306. As can be seen in FIG. 5, at a startup time t₀, when the output 452 of the flip flop 204 is high, the voltage 456 from the ramp signal source is allowed to ramp until it reaches the voltage level of the summing element output 458 at time t₁ and again at a time t₃, at which point the reset voltage 454 is pulled to zero and then returned to it's nominal HIGH value, which sets the output of the flip flop 204 to zero until the clock triggers the output 452 to go HIGH again at a time t₂.

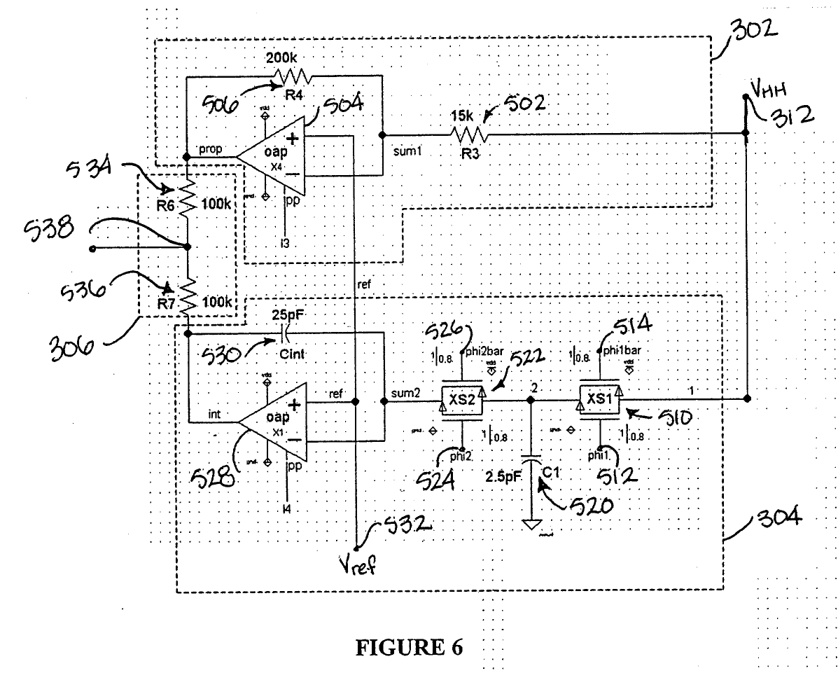

FIG. 6 is a schematic diagram of one embodiment of a proportional plus integral compensation network. The proportional amplifier 302 portion of the compensation network is shown implemented with a first resistor R3 502 whose output is fed into the inverting input of a first operational amplifier (op-amp) X4 504 and a second resistor R4 506. The output of resistor R4 506 is connected to the output of the X4 op-amp 504 such that it is in the feedback path of the op-amp 504. Although values for the resistors R3 502 and R4 506 to obtain a desired voltage amplification are shown in FIG. 6, the proportional amplifier 302 is not limited to these resistor values.

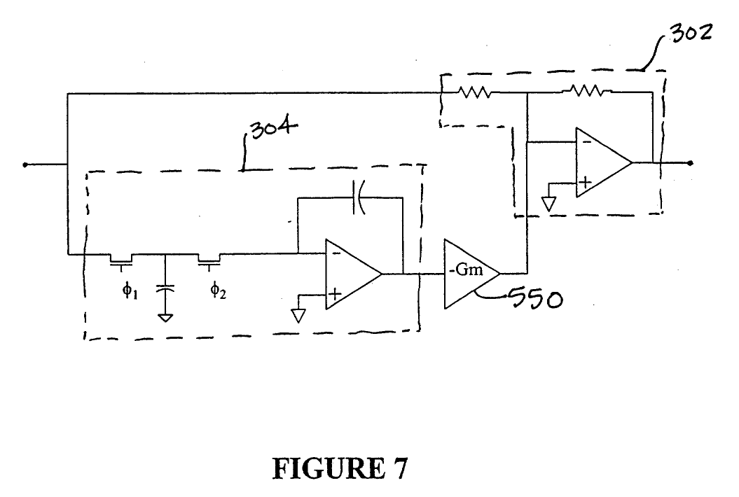

The integrator 304 portion of the compensation network is shown implemented in FIG. 6 with a first MOSFET analog switch XS1 510 comprising two MOSFET's, an NMOS and a PMOS transistor. The NMOS transistor has a clock gate input PHI1 512 and the PMOS transistor has an inverted clock gate input PHI1BAR 514. The gate inputs 512, 514 will be discussed further with respect to FIG. 7. The output of the first MOSFET analog switch XS1 510 is connected to the input of a capacitor C1 520, whose output is connected to ground, and to the input of a second MOSFET analog switch XS2 522. The second switching MOSFET XS2 522 also comprises two MOSFET's having a clock gate input PHI2 524 on the NMOS transistor and an inverted clock gate input PHI2BAR 526 on the PMOS transistor. The output of the second switching MOSFET XS2 522 is fed into the inverting input of a second op-amp X1 528 and a second capacitor Cint 530. The output of the capacitor Cint 530 is connected to the output of the op-amp X1 528 such that it is in the feedback path of the op-amp 528. The two op-amps X1 528 and X4 504 have a common non-inverting input from a variable reference voltage source 532. Although values for the capacitors C1 520 and Cint 530 to obtain a desired circuit function are shown in FIG. 6, the capacitors 520, 530 comprising the integrator 304 are not limited to these values.

The summing element 306 is implemented in the embodiment of FIG. 6 with a resistor network comprising a first resistor R6 534 having an input connected to the output of the first op-amp X4 504, and a second resistor R7 536 having an input connected to the output of the second op-amp X1 528. The two resistors 534, 536 have a common output node 538 which is the output of the proportional plus integral feedback compensation network. Although values for the resistors R6 534 and R7 536 are shown in the Figure, these are exemplary values and the summing network is not restricted to these values. Additionally, many types of resistive elements can be used to implement the summing element 306 such as switched capacitors, and to achieve greater voltage control range, the summing element 306 can alternatively be implemented with an active amplifier.

In an alternative embodiment of the proportional plus integral compensation network, the integrator 304 can be coupled to the summing node of the proportional amplifier 302 via an inverting transconductance amplifier 550, as illustrated in FIG. 7. The embodiment implementing the transconductance amplifier 550 can preserve the relative polarity of the output of the integrator 304 and the proportional amplifier 302, and allows the compensation loop to perform summation without an extra amplifier or summing element 306.

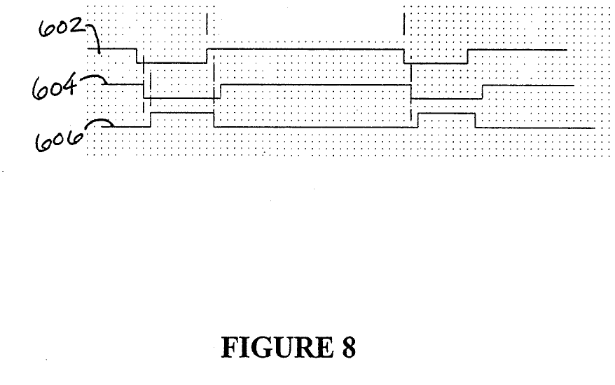

FIG. 8 is a timing diagram from a non-overlapping logic circuit (not shown) which provides the inputs PHI1 512, PHI1BAR 514, PHI2 524, and PHI2BAR 526 to the switching MOSFETs 510, 522 of the integrator 304 shown in FIG. 6. The clock input to the logic circuit, trace 602, is the same clock signal that is input to the flip flop 204. The PHI1 512 voltage 604 is a delayed version of the clock input 602 and the PHI2 524 voltage 606 is an inverted delayed version of the clock input 602. The transition points of the inputs 602, 604, and 606 do not overlap such that the PHI input 604 goes low a short delay after the input 602 goes low, and the PHI2 524 input 606 goes high a short delay after the PHI1 512 input 604 goes low, and the PHI2 524 input 606 goes low a short delay after the input 602 goes high, followed after a short delay by the PHI1 512 input 604 transitioning to a high state. The PHIBAR 514 input is the inversion of the PHI1 512 input, and the PHI2BAR 526 input is the inversion of the PHI2 524 input. The PHI 512, 524 and PHIBAR 514, 526 inputs provide the switch timing to charge and discharge the capacitor 520 so as to model an equivalent resistance equal to 1/(C1*f_{φ}), where f_{φ} is the frequency of the PHI inputs 512, 524. By judicious selection of the values of the clock frequency and the ratio of the capacitors C1/Cint, large values (and therefore large size) for the capacitor Cint 530 can be avoided.

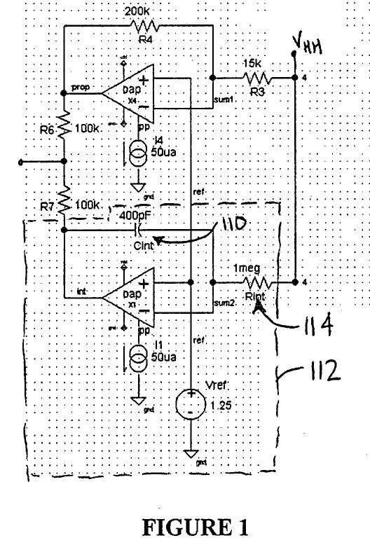

The switching MOSFET's XS1 and XS2 522, and the capacitor C1 520 of FIG. 6 act as a resistive element in the integrator 304, performing a similar function as the resistor Rint 114 in the prior art integrator shown in FIG. 1. While the integrator 112 of FIG. 1 and the integrator of FIG. 6 aim to perform the same overall function, FIG. 1 shows a value for Cint 110 of 400 pF, which is over an order of magnitude larger than the 25 pF Cint 530 shown in the integrator of FIG. 6, and the switching MOSFET's 510, 522 and capacitor 520 replace the large 1M Ohm Rint 114. The smaller value, and therefore smaller size, of the components of the integrator 304 of FIG. 6 greatly reduce the chip space needed to implement the compensation network. This reduced chip space increases the implementation environments the compensation network can be incorporated in, such as the regulator circuit of a portable video display screen.

The chip size of the compensation network of FIG. 6 is already reduced by use of the switched capacitor. Further reduction in size is achieved by combining the proportional and integral paths 302, 304 with the passive resistor summing network 306, which effectively increases the integrator time constant, thereby further reducing the size of the capacitor Cint 530 used in the integrator 304 of the compensation network.

Accordingly, the invention overcomes the longstanding problems in the industry of the large capacitor sizes used in integrators when implemented with linear components, and the instabilities created by discrete time components in proportional amplifiers. By combining the use of switched capacitors and linear components a proportional plus integral compensation network can be incorporated on chip.

The foregoing description details certain embodiments of the invention. It will be appreciated, however, that no matter how detailed the foregoing appears in text, the invention can be practiced in many ways. As is also stated above, it should be noted that the use of particular terminology when describing certain features or aspects of the invention should not be taken to imply that the terminology is being re-defined herein to be restricted to including any specific characteristics of the features or aspects of the invention with which that terminology is associated. The scope of the invention should therefore be construed in accordance with the appended claims and any equivalents thereof.

What is claimed is:

1. A compensation network circuit comprising:
a linear amplifier having an input and an output;
an integrator in parallel with said linear amplifier, having an input and an output, wherein said integrator includes a switched capacitor which provides an effective resistance; and
a summing element connected to said output of said linear amplifier and said output of said integrator so as to provide a stable, amplified feedback signal.

2. The compensation network circuit of claim 1, wherein said linear amplifier comprises:
a first resistor having an output and receiving an input signal from a voltage source;
an operational amplifier having an inverting input connected to said output of said first resistor;
a second resistor connected in the feedback path of said operational amplifier; and
a reference voltage input connected to a non-inverting input of said operational amplifier.

3. The compensation network circuit of claim 1, wherein said switched capacitor comprises
a first switch receiving a first clock input and having an output;
a first capacitor having an input connected to said output of said first switch and an output connected to ground; and
a second switch having a second clock input and an input connected to said first capacitor, and an output.

4. The compensation network circuit of claim 3, wherein said first switch and said second switch are switching MOSFET's.

5. The compensation network circuit of claim 3, wherein said integrator further comprises an operational amplifier having an inverting input connected to said output of said second switch, a non-inverting input connected to said reference voltage, and an output from said operational amplifier.

6. The compensation network circuit of claim 1, wherein said summing element is a passive resistor summing network.

7. The compensation network circuit of claim 1, wherein said summing element is an active amplifier.

8. The compensation network circuit of claim 1, implemented in a power conversion circuit.

9. The compensation network circuit of claim 1, implemented in a portable display device.

10. A compensation network circuit comprising:
an input voltage;
a proportional amplifier comprising:
a first impedance element receiving said input voltage, and an output connected to an inverting input of a first operational amplifier;
a reference voltage connected to a non-inverting input of said operational amplifier;
a second impedance element connected in the feedback path of said operational amplifier, and an output from said first operational amplifier;
an integrator comprising:
a first switch receiving said input voltage and a first clock signal, and having an output;
a first capacitor receiving said output of said first switch, and an output connected to ground;
a second switch connected to said first capacitor, receiving a second clock signal, and having an output;
a second operational amplifier having an inverting input from said output of said second switch, a non-inverting input receiving said reference voltage, a second capacitor in a feedback path of said second operational amplifier, and an output from said second operational amplifier; and
a summing element, having an input from said output of said first operational amplifier and said output of said second operational amplifier, and having an output so as to provide a stable, amplified feedback signal.

11. The circuit of claim 10, wherein said first switch and said second switch are switching MOSFET's.

12. The circuit of claim 10, wherein said summing element comprises a first resistive element receiving an input from said output of said first operational amplifier and an output, and a second resistive element receiving an input from said output of said second operational amplifier and having an output connected to said output of said first resistive element of said summing network

13. A compensation network circuit comprising:
a voltage input;
a clock input;
a flip flop receiving said voltage input, and having a reset input, an output, and an inverted output;
a boost circuit connected to said output of said flip flop, and having a voltage output;
a linear amplifier receiving said voltage output, and having an output;
an integrator in parallel with said linear amplifier, receiving said voltage output, and having an output, and wherein said integrator includes a switched capacitor which provides an effective resistance;
a summing element connected to said output of said linear amplifier and said output of said integrator so as to provide a stable, amplified feedback signal; and
a switch control circuit receiving said stable, amplified feedback signal from said summing network and having an input and an output, wherein said output is connected to said reset input of said flip flop.

14. A method of loop compensation comprising:
proportionally amplifying an input with a linear amplifier;
integrating said input using at least one switched capacitor; and
summing said amplified input and said integrated input so as to produce a stable, amplified feedback signal.

15. The method of claim 14, wherein said summing is performed by a passive resistor summing network.

16. The method of claim 14, wherein said summing is performed by an active amplifier.

17. The method of claim 14, further comprising controlling a power converter circuit using said method of loop compensation.

18. The method of claim 14, wherein said method is performed in a portable display device.

19. A compensation network circuit comprising:
a signal input;
a first signal path having linear components and an output, and receiving said signal input;
a second signal path having at least one switched capacitor and an output, and receiving said signal input; and
a summing element receiving a signal from said output of said first path and an output of said second path so as to provide a stable, amplified output signal.

20. The circuit of claim 19, wherein said first signal path comprises a first resistor receiving said signal input, an operational amplifier having an input connected to an output of said first resistor and an input receiving a reference voltage, a second resistor in a feedback path of said operational amplifier, and an output connected to an output of said operational amplifier.

21. The circuit of claim 19, wherein said switched capacitor comprises:
a first switch receiving a first clock input and having an output;
a first capacitor having an input connected to said output of said first switch and an output connected to ground; and
a second switch having a second clock input and an input connected to said first capacitor, and an output.

22. The circuit of claim 21, wherein said first switch and said second switch are switching MOSFET's.

23. The circuit of claim 19, wherein said second signal path comprises an integrator.

24. A compensation network circuit comprising:
means for proportionally amplifying a signal input with a linear amplifier;
means for integrating said signal input using at least one switched capacitor; and
means for summing said amplified signal and said integrated signal so as to provide a stable, amplified signal.

25. The circuit of claim 24, wherein said switched capacitor comprises:
a first switch receiving a first clock input and having an output;
a first capacitor having an input connected to said output of said first switch and an output connected to ground; and
a second switch having a second clock input and an input connected to said first capacitor, and an output.

26. The circuit of claim 25, wherein said first switch and said second switch are switching MOSFET's.

27. The circuit of claim 24, wherein said summing is performed by a passive resistor summing network.

28. The circuit of claim 24, wherein said summing is performed by an active amplifier.

29. The circuit of claim 24, further comprising controlling a power converter circuit using said method of loop compensation.

30. The circuit of claim 24, wherein said method is performed in a portable display device.

31. A compensation network circuit, comprising:
a signal input;
a first signal path, receiving said signal input and having an output;
a second signal path, receiving said signal input and having an output, comprising:
an integrator, having an input and an output, wherein said integrator includes a switched capacitor which provides an effective resistance;
a transconductance amplifier, having an input coupled to said output of said integrator, and an output; and
a linear amplifier having an input coupled to said output of said first signal path and said output of said second signal path, and an output so as to provide a stable, amplified feedback signal.

32. The compensation circuit of claim 31, wherein said first signal path has an input from a voltage source and comprises a resistor having an output.

33. The compensation circuit of claim 31, wherein said linear amplifier comprises:
an operational amplifier having an inverting input connected to said first signal path and said output of said transconductance amplifier; and
a resistor connected in the feedback path of said operational amplifier.

34. The compensation circuit of claim 31, wherein said switched capacitor comprises
a first switch receiving a first clock input and having an output;
a first capacitor having an input connected to said output of said first switch and an output connected to ground; and
a second switch having a second clock input and an input connected to said first capacitor, and an output.

35. The compensation circuit of claim 34, wherein said first switch and said second switch are switching MOSFET's.

36. The compensation circuit of claim 34, wherein said integrator further comprises an operational amplifier having an inverting input connected to said output of said second switch, a non-inverting input connected to said reference voltage, and an output from said operational amplifier.

37. The compensation circuit of claim 31, implemented in a power conversion circuit.

38. The compensation circuit of claim 31, implemented in a portable display device.
